(19) United States
(12) Patent Application Publication
(10) Pub. No.: US 2026/0076117 A1
(43) Pub. Date: Mar. 12, 2026

(54) METHOD FOR DOPING MOLYBDENUM DISULFIDE THIN FILM WITH ALUMINUM NITRIDE, AND ALUMINUM NITRIDE FOR THE SAME

(71) Applicant: University of seoul Industry Cooperation Foundation, Seoul (KR)

(72) Inventors: Moonsup HAN, Seoul (KR); Sangwoo NAM, Sangju-si (KR); Beomjin PARK, Ulsan (KR); Minseon GU, Suwon-si (KR); Hanyeol AHN, Seoul (KR); Jaehui IM, Daejeon (KR); Hyun Su PARK, Ulsan (KR); Young Jun CHANG, Seoul (KR)

(73) Assignee: University of seoul Industry Cooperation Foundation, Seoul (KR)

(21) Appl. No.: 18/936,641

(22) Filed: Nov. 4, 2024

(30) Foreign Application Priority Data
Sep. 10, 2024 (KR) 10-2024-0123236

(51) Int. Cl. H01L 21/385; H01L 21/02; H01L 29/24; H01L 29/76

(52) U.S. Cl. CPC H10P 32/14; H10D 48/362; H10D 62/80; H10P 14/3436; H10P 14/6329; H10P 14/69391; H10P 32/17

(57) ABSTRACT

Disclosed is a semiconductor doping method, and the semiconductor doping method includes: forming a molybdenum disulfide (MoS₂) layer on a substrate; sputtering and depositing an aluminum nitride (AlOxNy) thin film on a surface of the molybdenum disulfide (MoS₂) layer; and injecting electrons into the molybdenum disulfide (MoS₂) through the deposition of the aluminum nitride (AlOxNy) thin film.

### TECHNICAL FIELD

The present disclosure relates to aluminum oxynitride used for doping molybdenum disulfide, a molybdenum disulfide doping method, and a molybdenum disulfide semiconductor manufactured using the method.

### BACKGROUND

Atomic Layer Deposition (ALD) is a technique for depositing an extremely thin and uniform thin film at an atomic layer level, and the ALD is also used for doping.

ALD doping may generally provide desired electrical properties by activating or diffusing doping elements through post-doping heat treatment.

Recently, two-dimensional (2D) materials such as MoS₂ are used for semiconductor doping, and such materials exhibit properties different from traditional three-dimensional semiconductors. The 2D materials have a layered structure with atomic thickness, which offers unique advantages in electrical and optical properties. These materials may be crucial in next-generation electronic devices and sensor technologies.

### PRIOR ART LITERATURE

### Patent Document

Korean Patent No. 10-1904383

### SUMMARY

An object of the present disclosure is to successfully reduce fixed charges that may occur inside a thin film even when a process is performed at room temperature, unlike conventional atomic layer deposition methods.

Another object of the present disclosure is to manufacture a semiconductor by a low-temperature process (e.g., below 150° C.) to enable partial doping using a photoresist.

Another object of the present disclosure is to prevent the deformation of a bendable substrate by manufacturing a semiconductor using a low-temperature process (e.g., below 150C.).

In one aspect, a semiconductor doping method is provided, including: forming a molybdenum disulfide (MoS₂) layer on a substrate; sputtering and depositing an aluminum nitride (AlOxNy) thin film on a surface of the molybdenum disulfide (MoS₂) layer; and injecting electrons into the molybdenum disulfide (MoS₂) through the deposition of the aluminum nitride (AlOxNy) thin film.

There may be no process of injecting the electrons and no process of applying heat after the electrons are injected, or a temperature of a heat treatment process may be 150° C. or less.

The aluminum nitride may be composed such that an oxygen ratio x is in a range of 0.5 to 1.2 and a nitrogen ratio y is in a range of 0.3 to 0.7 when an aluminum ratio is 1.

The injecting of the electrons may be surface charge transfer doping (SCTD) through deposition of aluminum nitride (AlOxNy) on the surface of the molybdenum disulfide (MoS₂) layer.

In another aspect, a semiconductor manufactured by doping is provided, the semiconductor in which: a molybdenum disulfide (MoS₂) layer is formed on a substrate; an aluminum nitride (AlOxNy) thin film is sputtered and deposited on a surface of the molybdenum disulfide (MoS₂) layer; and electrons are injected into the molybdenum disulfide (MoS₂) through deposition of the aluminum nitride thin film.

There may be no process of injecting the electrons and no process of applying heat after the electrons are injected, or a temperature of a heat treatment process may be 150° C. or less.

The aluminum nitride may be composed such that an oxygen ratio x is in a range of 0.5 to 1.2 and a nitrogen ratio y is in a range of 0.3 to 0.7 when an aluminum ratio is 1.

The injecting of the electrons may be surface charge transfer doping (SCTD) through deposition of aluminum nitride (AlOxNy) on the surface of the molybdenum disulfide (MoS₂) layer.

In yet another aspect, a semiconductor is provided, including a molybdenum disulfide (MoS₂) layer formed on a substrate; an aluminum nitride (AlOxNy) thin film sputtered and deposited on a surface of the molybdenum disulfide (MoS₂) layer; and doping is carried out by injecting electrons into the molybdenum disulfide (MoS₂) through deposition of the aluminum oxynitride thin film, so that partial doping is possible using a photoresist.

In addition, the semiconductor may be characterized in that a doping process is possible even on molybdenum disulfide deposited on a flexible substrate that is sensitive to heat.

According to the present disclosure, since the fixed charge possibly occurring within a semiconductor thin film may be effectively reduced, it is possible to improve the responsiveness of a device.

In addition, according to the present disclosure, a heat treatment process is omitted in a semiconductor process, so that substrate deformation due to high temperatures is prevented, as well as irreversible changes or impacts on the electrodes.

In addition, according to the present disclosure, since a semiconductor may be manufactured through a low-temperature process (e.g., below 150° C.), it is possible to carry out partial or selective doping that was highly constrained in conventional high-temperature processes.

In addition, according to the present disclosure, it is possible to prevent deformation of a flexible substrate by manufacturing a semiconductor using a low-temperature process (e.g., below 150° C.).

### BRIEF DESCRIPTION OF THE DRAWINGS

FIG. 1 is a flowchart of a semiconductor doping method of the present disclosure.

FIG. 2 is a drawing explaining the principle of a charge transfer doping method used in the present disclosure.

FIG. 3 shows the structure of a device used for doping verification in the present disclosure.

FIG. 4 is a graph showing the transfer characteristic curves of a device before and after aluminum nitride deposition in the present disclosure.

FIG. 5 is a graph showing the capacitance versus voltage of aluminum nitride synthesized in the present disclosure.

### DETAILED DESCRIPTION

In describing the embodiments of this specification, if it is determined that a detailed description of a known technology related to this specification may unnecessarily obscure the gist of this specification, the detailed description will be omitted. In addition, the terms described below are terms defined in consideration of the functions in this specification, and may vary depending on the intention or custom of the user or operator. Therefore, the definition of the terms should be based on the contents throughout this specification. The terms used in the detailed description are intended only to describe embodiments of the present specification only and should not be construed as limiting. Unless clearly used otherwise, expressions in the singular form include the meaning of the plural form. In this description, expressions such as “including” or “comprising” are intended to refer to certain characteristics, numbers, steps, operations, components, parts, or combinations thereof, and should not be construed to exclude the existence or possibility of one or more other characteristics, numbers, steps, operations, components, parts, or combinations thereof, other than those described.

Although the terms including an ordinal number such as first, second, etc. can be used for describing various components, the components are not restricted by the terms. These terms are used nominatively only to distinguish one component from another, and the order of their relationships is determined by the context of their descriptions rather than by the terms themselves.

The term “and/or” is used to encompass all possible combinations of a plurality of items being referred to. For example, “A and/or B” means any of the following: “A”, “B”, or “A and B”.

When a component is referred to as being “connected” or “accessed” to other component, it should be understood that not only is the component directly connected or accessed to the other component, but also, another component may exist therebetween.

Hereinafter, specific embodiments of the present disclosure will be described with reference to the drawings. The following detailed description is provided to facilitate a comprehensive understanding of the methods, devices and/or articles described herein. However, this is only an example and the present disclosure is not limited thereto.

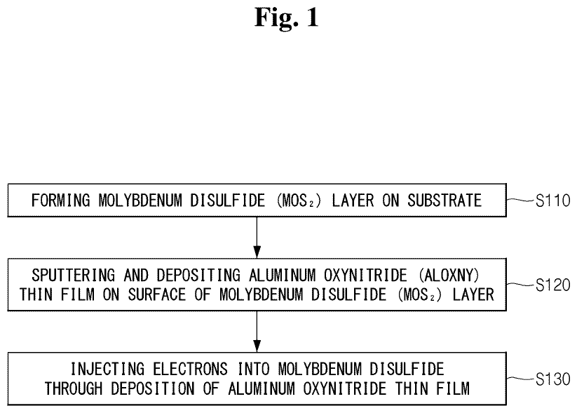

FIG. 1 is a flowchart of a semiconductor doping method of the present disclosure.

In general, ion implantation doping in two-dimensional semiconductor materials causes significant structural damage to a semiconductor. In addition, even when surface charge transfer doping (SCTD) is used, there is the issue of reduced electron mobility.

Furthermore, although annealing can be used in conventional semiconductor doping methods, such annealing causes deformation of molybdenum disulfide (MoS2), which limits the improvement of device properties using SCTD.

Referring to FIG. 1, a semiconductor doping method according to the present disclosure may include: forming a molybdenum disulfide (MoS₂) layer on a substrate (S110); sputtering and depositing an aluminum oxynitride (AlOxNy)thin film on a surface of the molybdenum disulfide (MoS₂) layer (S120); and injecting electrons into the molybdenum disulfide (MoS₂) through deposition of the aluminum oxynitride (AlOxNy) thin film (S130).

For example, the substrate of the present disclosure may be silicon oxide, and the molybdenum disulfide (MoS₂) may be exfoliated using tape and transferred onto the silicon oxide.

For example, in the present disclosure, injecting electrons may be surface charge transfer doping (SCTD) through the deposition of aluminum oxynitride (AlOxNy).

In the present disclosure, surface charge transfer doping (SCTD) using aluminum oxynitride (AlOxNy) was successfully applied to achieve damage-free doping of MoS₂ without additional annealing.

After the doping process of the present disclosure, the channel carrier concentration significantly increased to 1.2×10¹² (cm⁻²). Moreover, this increase in carrier concentration was achieved without the need for an additional annealing step while maintaining channel mobility.

In other words, the semiconductor doping method of the present disclosure is characterized by not having a process of injecting electrons and not having a process of applying heat after the electrons are injected.

Additionally, in the present disclosure, the aluminum oxynitride (AlOxNy) thin film may be characterized by an oxygen ratio x in a range of 0.5 to 1.2 and a nitrogen ratio y in a range of 0.3 to 0.7 when an aluminum ratio is 1.

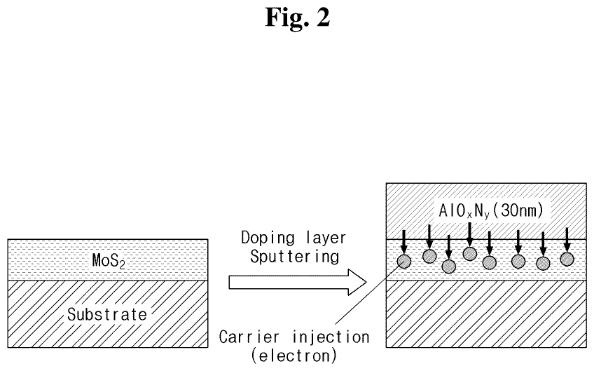

FIG. 2 is a drawing explaining the principle of a charge transfer doping method used in the present disclosure.

Referring to FIG. 2, in the present disclosure, an aluminum oxynitride layer may be deposited onto molybdenum disulfide (MoS₂) with a thickness of 30 nm. In addition, in the present disclosure, electrons may be injected into the molybdenum disulfide (MoS₂) through sputtering of the doping layer carried out at room temperature.

As shown in FIG. 2, the carrier concentration of the molybdenum disulfide (MoS₂) layer increases as electrons are injected after the sputtering deposition of aluminum nitride (AlOxNy) at room temperature.

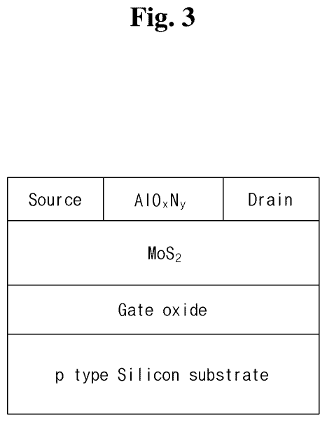

FIG. 3 shows the structure of a device used for doping verification in the present disclosure.

To verify a doping method of the present disclosure and confirm the feasibility of implementing an actual device, a field-effect transistor (FET) as shown in FIG. 3 was used.

For example, a doping layer in the present disclosure may be characterized by an oxygen ratio x in a range of 0.5 to 1.2 and a nitrogen ratio y in a range of 0.3 to 0.7 when an aluminum ratio is 1.

The molybdenum disulfide (MoS₂) layer serves as a semiconductor layer where electron movement occurs. The molybdenum disulfide (MoS₂) layer in the present disclosure, which is a two-dimensional semiconductor layer, may exhibit excellent electron mobility.

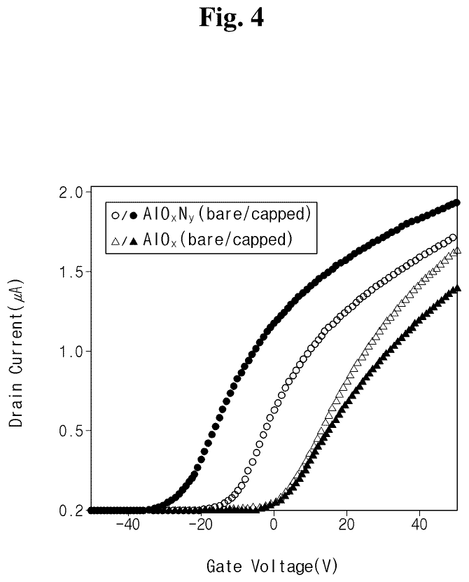

FIG. 4 is a graph showing the transfer characteristic curves of a device before and after aluminum nitride deposition in the present disclosure.

In the graph of FIG. 4, the bare curve (unfilled red) represents the transfer characteristic curve of a transistor without aluminum oxynitride (AlOxNy) deposition, while the capped curve (filled red) represents the transfer characteristic curve of a transistor with aluminum oxynitride (AlOxNy) deposition.

When the doping method of the present disclosure was applied to an actual field-effect transistor (FET), the transfer characteristic curve shifted to the left after the deposition of aluminum oxynitride (AlOxNy) compared to before the deposition. This shift indicates that electrons were injected into the molybdenum disulfide (MoS₂) after the deposition of aluminum oxynitride. In addition, it can be confirmed that the slope of the linear region remained unchanged before and after thin-film deposition, indicating that the electron mobility within the molybdenum disulfide (MoS₂) was not affected.

In the graph of FIG. 4, as a comparative example to the present disclosure, the bare curve (unfilled gray) represents the transfer characteristic curve of a transistor without aluminum oxide deposition, while the capped curve (filled gray) represents the transfer characteristic curve of a transistor with aluminum oxide deposition.

Compared to the present disclosure, it can be observed that the slope in the linear region of the transfer characteristic curve decreases in the transistor with aluminum oxide deposition in the comparative example.

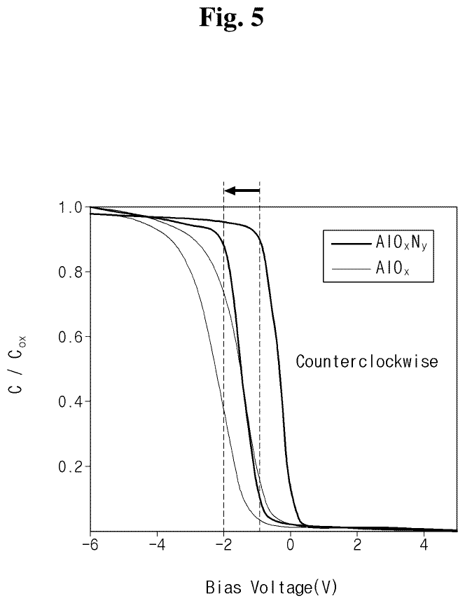

FIG. 5 is a graph showing the capacitance versus voltage of aluminum nitride synthesized in the present disclosure.

FIG. 5 shows that aluminum oxynitride exhibits a smaller shift in the neutral position compared to aluminum oxide. This indicates that aluminum oxynitride has fewer fixed charges within the thin film compared to aluminum oxide. Therefore, the present disclosure is free from the degradation of charge transfer characteristics in the molybdenum disulfide (MoS₂) channel caused by these fixed charges.

A semiconductor manufactured according to a doping method of the present disclosure may be applied to all electronic devices that utilize molybdenum disulfide (MoS₂) as a channel, such as a field-effect transistor (FET) and an optical sensor. In particular, since no heat treatment is required, this method may be applied to flexible devices. Moreover, since partial doping can be achieved using a photoresist, this method may be applied to functional integrated circuits (such as diodes and rectifiers, through selective doping).

In the present disclosure, doping is achieved by simply depositing aluminum oxynitride on the surface of the molybdenum disulfide (MoS₂) layer, allowing for electron injection, and importantly, this process does not require any heat treatment.

That is, it is possible to inject a similar amount of electrons (1.2×10¹² cm⁻²) during the electron injection process without damaging the channel or wafer, similar to conventional methods.

Unlike conventional charge transfer doping methods, the present disclosure enables partial or selective doping using a photoresist, making it possible to implement various types of devices (such as diodes and rectifiers) using charge transfer doping in a two-dimensional semiconductor. In addition, due to the room-temperature processing characteristics employed in the present disclosure, it is safe from deformation of the metal electrodes, which are essential for all electronic devices, thereby significantly increasing the degree of freedom of a device process.

The description of the present specification as set forth above is for illustrative purposes only, and a person skilled in the art to which the present disclosure pertains may readily understand that the present disclosure may be easily modified into other specific forms without changing the technical idea or essential characteristics of the embodiments. Therefore, it should be understood that the embodiments described above are exemplary in all respects and not limiting.

The scope of the present disclosure is indicated by the claims described below rather than the detailed description above, and all changes or modifications derived from the meaning and scope of the claims and their equivalent concepts should be interpreted as being included in the scope of the present disclosure.

What is claimed is:

1. A semiconductor doping method comprising:
forming a molybdenum disulfide (MoS2) layer on a substrate;
sputtering and depositing an aluminum nitride (AlOxNy) thin film on a surface of the molybdenum disulfide (MoS₂) layer; and
injecting electrons into the molybdenum disulfide (MoS₂) through the deposition of the aluminum nitride (AlOxNy) thin film.

2. The semiconductor doping method of claim 1, wherein there is no process of injecting the electrons and no process of applying heat after the electrons are injected, or a temperature of a heat treatment process is 150°C. or less.

3. The semiconductor doping method of claim 1, wherein the aluminum nitride is composed such that an oxygen ratio x is in a range of 0.5 to 1.2 and a nitrogen ratio y is in a range of 0.3 to 0.7 when an aluminum ratio is 1.

4. The semiconductor doping method of claim 1, wherein the injecting of the electrons is surface charge transfer doping (SCTD) through deposition of aluminum nitride (AlOxNy) on the surface of the molybdenum disulfide (MoS₂) layer.

5. A semiconductor manufactured by doping, the semiconductor in which:
a molybdenum disulfide (MoS2) layer is formed on a substrate;
an aluminum nitride (AlOxNy) thin film is sputtered and deposited on a surface of the molybdenum disulfide (MoS₂) layer; and
electrons are injected into the molybdenum disulfide (MoS₂) through deposition of the aluminum nitride thin film.

6. The semiconductor of claim 5, wherein there is no process of injecting the electrons and no process of applying heat after the electrons are injected, or a temperature of a heat treatment process is 150°C. or less.

7. The semiconductor of claim 5, wherein the aluminum nitride is composed such that an oxygen ratio x is in a range of 0.5 to 1.2 and a nitrogen ratio y is in a range of 0.3 to 0.7 when an aluminum ratio is 1.

8. The semiconductor of claim 5, wherein the injecting of the electrons is surface charge transfer doping (SCTD) through deposition of aluminum nitride (AlOxNy) on the surface of the molybdenum disulfide (MoS₂) layer.

9. A semiconductor comprising:
a molybdenum disulfide (MoS₂) layer formed on a substrate; and
an aluminum nitride (AlOxNy) thin film sputtered and deposited on a surface of the molybdenum disulfide (MoS₂) layer,
wherein doping is carried out by injecting electrons into the molybdenum disulfide (MoS₂) through deposition of the aluminum oxynitride thin film, so that partial doping is possible using a photoresist.
